(19) United States
(12) Patent Application Publication
(10) Pub. No.: US 2012/0081804 A1
(43) Pub. Date: Apr. 5, 2012

(54) DRIVING MECHANISM, LENS BARREL, AND CAMERA

(75) Inventors: Kunihiro KUWANO, Kawasaki-shi (JP); Hiromoto KANEMITSU, Funabashi-shi (JP)

(73) Assignee: NIKON CORPORATION, Tokyo (JP)

(21) Appl. No.: 13/248,627

(22) Filed: Sep. 29, 2011

(30) Foreign Application Priority Data
Sep. 30, 2010 (JP) 2010-220832
Sep. 30, 2010 (JP) 2010-220833
Sep. 30, 2010 (JP) 2010-220834

(51) Int. Cl. G02B 7/04; H01L 41/09; H01L 41/04

(52) U.S. Cl. 359/824; 310/333

(57) ABSTRACT

A driving mechanism includes a first piezoelectric element that vibrates in a thickness-shear vibration mode in a first direction, a first member that is driven to vibrate in the first direction by the first piezoelectric element, a second piezoelectric element that is supported by the first member and that vibrates in the thickness-shear vibration mode in a second direction, and a second member that is driven to vibrate in the second direction by the second piezoelectric element.

### BACKGROUND

1. Field of the Invention

The present invention relates to a driving mechanism, a lens barrel, and a camera.

2. Description of Related Art

A driving mechanism using a piezoelectric element has been known hitherto. In such a driving mechanism, a driving target member is driven by driving plural piezoelectric elements and causing tip members coming in contact with the driving target member to move elliptically. For example, JP-A-2007-236138 discloses a driving mechanism that drives a driving target member in the X axis direction through the elliptical movement of the tip members parallel to the XZ plane when an XYZ orthogonal coordinate system is set up.

### SUMMARY

However, the driving mechanism disclosed in JP-A-2007-236138 has a problem in that the vibration in the lifting direction in which the distance between a tip member and a base member varies and the vibration in the feed direction in which the distance between the tip member and the base member does not vary cannot be independently controlled. There is also a problem in that it is difficult to cause the tip member to efficiently vibrate in the lifting direction and the feed direction.

There is also a problem in that it is not possible to stably drive a member to be driven by the piezoelectric elements due to the undesired vibration generated by the vibrations of the piezoelectric elements in the lifting direction and the feed direction.

There is also a problem in that the driving mechanism may undergo fatigue failure due to the vibrations of the piezoelectric elements in the lifting direction and the feed direction.

An object of some aspects of the invention is to provide a driving mechanism which can independently control vibrations in two different directions of a member to be driven by piezoelectric elements. Another object of some aspects of the invention is to provide a driving mechanism which can cause a member to be driven by piezoelectric elements to efficiently vibrate in two different directions.

Still another object of some aspects of the invention is to provide a driving mechanism which can stably drive the member driven by piezoelectric elements.

Still another object of some aspects of the invention is to provide a driving mechanism which can suppress the fatigue failure of the driving mechanism.

Still another object of some aspects of the invention is to provide a lens barrel and a camera having the driving mechanism.

Some aspects of the invention employ the following configurations. For purposes of ease of explanation of the invention, the invention will be described below with reference to reference signs of the accompanying drawings illustrating an embodiment, but the invention is not limited to the embodiment.

According to an aspect of the invention, there is provided a driving mechanism including: a first piezoelectric element that vibrates in a thickness-shear vibration mode in a first direction; a first member that is driven to vibrate in the first direction by the first piezoelectric element; a second piezoelectric element that is supported by the first member and that vibrates in the thickness-shear vibration mode in a second direction; and a second member that is driven to vibrate in the second direction by the second piezoelectric element.

According to another aspect of the invention, there is provided a driving mechanism including: a first piezoelectric element that vibrates in a thickness-shear vibration mode in a first direction; a first member that is driven to vibrate in the first direction by the first piezoelectric element; a second piezoelectric element that is supported by the first member and that vibrates in the thickness-shear vibration mode in a second direction different from the first direction; and a second member that is driven to vibrate in the second direction by the second piezoelectric element, wherein the first member supports the first piezoelectric element on a first face parallel to the first direction and supports the second piezoelectric element on a second face parallel to the second direction, and a plurality of the first piezoelectric elements having a long-side in the first direction are arranged on the first face with an interval therebetween in a short-side direction of the first piezoelectric element.

According to still another aspect of the invention, there is provided a lens barrel including: the driving mechanism; a cam box that is driven by the driving mechanism; and a lens that is movably supported by the cam box to adjust the focus.

According to still another aspect of the invention, there is provided a camera including: the lens barrel; and an imaging device that forms a subject image on an imaging plane through the use of the lens disposed in the lens barrel.

According to still another aspect of the invention, there is provided a driving mechanism including: a first piezoelectric element that vibrates in a thickness-shear vibration mode in a first direction; a first member that is driven to vibrate in the first direction by the first piezoelectric element; a second piezoelectric element that is supported by the first member and that vibrates in the thickness-shear vibration mode in a second direction different from the first direction; and a second member that is driven to vibrate in the second direction by the second piezoelectric element, wherein the first member supports the first piezoelectric element on a first face parallel to the first direction and supports the second piezoelectric element on a second face parallel to the second direction, and the first piezoelectric element and the second piezoelectric element are separated from each other.

According to still other aspects of the invention, there are provided a lens barrel and a camera which include the driving mechanism.

In the driving mechanism according to the aspects of the invention, it is possible to independently control vibrations in two different directions of a member driven by piezoelectric elements. It is also possible to cause a member to be driven by piezoelectric elements to efficiently vibrate in two different directions. It is also possible to stably drive the member to be driven by piezoelectric elements. It is also possible to suppress the fatigue failure of the driving mechanism. According to the aspects of the invention, it is possible to provide a lens barrel and a camera having the driving mechanism.

### BRIEF DESCRIPTION OF THE DRAWINGS

FIG. 1 is a front view of a driving mechanism according to a first embodiment of the invention.

FIGS. 2A and 2B are circuit diagrams of the driving mechanism according to the first embodiment.

FIG. 3 is a partially-enlarged view illustrating a first modification of the driving mechanism according to the first embodiment.

FIG. 4 is a partially-enlarged view illustrating a second modification of the driving mechanism according to the first embodiment.

FIG. 5 is a diagram schematically illustrating the configurations of a lens barrel and a camera including the driving mechanism according to the first embodiment of the invention.

FIG. 6 is a front view of a driving mechanism according to second and third embodiments of the invention.

FIG. 7A is a circuit diagram of the driving mechanism according to the second and third embodiments.

FIG. 7B is a circuit diagram of the driving mechanism according to the second and third embodiments.

FIG. 8 is a perspective view illustrating an arrangement state of piezoelectric elements of the driving mechanism according to the second embodiment.

FIG. 9 is a perspective view of a base member of the driving mechanism according to the second embodiment.

FIG. 10 is a front view of a driving member of the driving mechanism according to the third embodiment.

FIGS. 11A and 11B are front views illustrating the operation of a driving member of the driving mechanism according to the third embodiment.

### DESCRIPTION

Hereinafter, embodiments of the invention will be described with reference to the accompanying drawings. The embodiments are only examples of the invention and do not limit the invention, but can be modified in various forms within the technical concept of the invention. In the drawings, for purposes of ease of understanding, the scales and the numbers are different between actual structures and the shown structures.

A driving mechanism according to a first embodiment of the invention performs a relative driving operation of displacing a rotor relative to a base member and drives an optical device or an electronic device, such as a lens barrel of a camera through the use of the rotor.

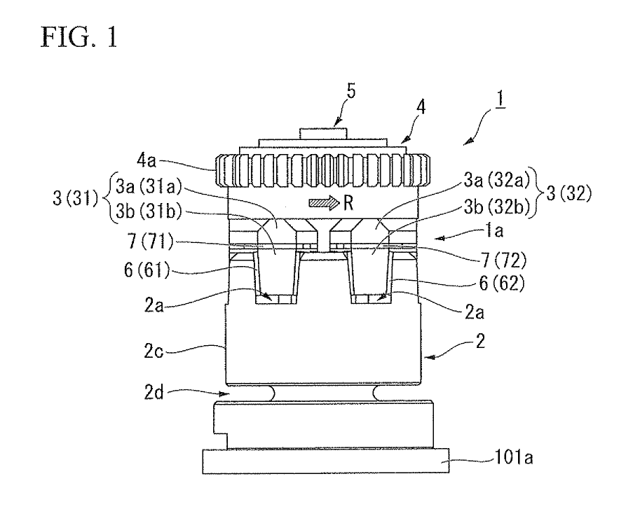

As shown in FIG. 1, the driving mechanism 1 includes a base member 2, driving members 3, a rotor 4, a support shaft 5, first piezoelectric elements 6, and second piezoelectric elements 7.

The base member 2 is formed of a conductive material such as stainless steel which can be considered as an elastic body. The base member 2 has a hollow cylindrical shape having a through-hole in the shaft direction at the center thereof. The surface of the base member 2 is subjected to insulating treatment and, for example, an insulating film is formed thereon. The support shaft 5 is inserted into the through-hole of the base member 2.

Plural holding portions 2a are formed at one end portion of the base member 2 so as to be adjacent to each other in the circumferential direction of the base member 2. Each holding portion 2a has a concave shape supporting the corresponding driving member 3 with the driving member 3 interposed between both sides in the circumferential direction of the base member 2. The other end of the base member 2 is fixed to a mounting section 101a through the use of a fastening member such as bolts not shown. A groove portion 2d which is continuous in the circumferential direction is formed in the part closer to the mounting section 101a than the center of the base member 2.

The driving mechanism 1 includes two groups of which each includes three driving members 3 and which are driven with a predetermined phase difference. In this embodiment, out of six driving members 3 arranged at an equal interval in the circumferential direction of the base member 2, three driving members 31 belong to the first group and three driving members 32 belong to the second group. The driving members 31 of the first group and the driving members 32 of the second group are alternately arranged in the circumferential direction of the base member 2, that is, in the rotation direction R of the rotor 4.

Each driving member 3 includes a base portion (the first member) 3b and a tip portion (the second member) 3a.

The base portion 3b has a substantially rectangular parallelepiped shape of which a pair of side faces intersecting the circumferential direction is slightly inclined. The base portion 3b is formed of, for example, light metal alloy and has conductivity. The base portion 3b is supported by the corresponding holding portion 2a so as to be movable in the direction parallel to the support shaft 5.

The tip portion 3a has a hexagonal prism shape having a mounting-like cross-section viewed from the radial direction of the base member 2. The tip portion 3a is formed of, for example, stainless steel and has conductivity. The tip portion 3a is disposed between the base portion 3b and the rotor 4 and protrudes from the holding portion 2a to support the rotor 4.

The rotor 4 is mounted on the support shaft 5 via bearings (not shown) and is disposed to be rotatable forward and backward in the rotation direction R about the support shaft 5. A gear 4a used to drive, for example, a lens barrel of a camera is formed on the outer circumferential surface of the rotor 4. The surface of the rotor 4 facing the base member 2 is supported by plural driving members 3.

The support shaft 5 is a circular rod-like member of which the center line corresponds to the rotation shaft of the rotor 4. One end of the support shaft 5 is fixed to the mounting section 101a. The support shaft 5 passes through the base member 2 and the rotor 4. The support shaft 5 is disposed at the center of plural driving members 3 arranged in the rotation direction R of the rotor 4.

The first piezoelectric element 6 is formed of a material containing, for example, piezoelectric zirconate titanate (PZT). The first piezoelectric element 6 is disposed between the inner face of the corresponding holding portion 2a of the base member 2 and the side face of the base portion 3b of the driving member 3. The first piezoelectric elements 6 are disposed to interpose the base portion 3b of the driving member 3 between the front side and the rear side in the rotation direction R of the rotor 4. Two first piezoelectric elements 6 are disposed on each of the front and rear side faces of the base portion 3b of the driving member 3 in the rotation direction R of the rotor 4. The two first piezoelectric elements 6 on each side face are arranged to be adjacent to each other in the diameter direction of the base member 2, that is, in the diameter direction of the rotor 4.

Each first piezoelectric element 6 has a strip-like shape which is long in the shaft direction of the support shaft 5. The first piezoelectric element 6 is disposed to vibrate in a thickness-shear vibration mode in the long-side direction parallel to the shaft direction (the first direction) of the support shaft 5. Each first piezoelectric element 6 is bonded to both the inner face of the corresponding holding portion 2a of the base member 2 and the side face of the base portion 3b of the driving member 3 with a conductive adhesive.

Here, the thickness direction of the first piezoelectric element 6 is defined as a direction tangential to the turning circle of the rotor 4 at the centers of the driving members 3, that is, a direction tangential to the central circle passing through the centers of the driving members 3. At this time, the longitudinal elastic coefficient in the thickness direction of the first piezoelectric element 6 is greater than the transverse elastic coefficient in the long-side direction thereof.

For example, when the vibration mode of the first piezoelectric element 6 is a longitudinal-effect thickness-shear vibration mode, the longitudinal elastic coefficient of the first piezoelectric element 6 is about 167 GPa and the transverse elastic coefficient thereof is about 25 GPa. That is, the transverse elastic coefficient of the first piezoelectric element 6 is about ⅙ times the longitudinal elastic coefficient.

Similarly, the longitudinal elastic coefficient of the base member 2 is also greater than the transverse elastic coefficient thereof. For example, when the base member 2 is formed of SUS304 as a main component, the longitudinal elastic coefficient thereof is about 193 GPa and the transverse elastic coefficient thereof is about 69 GPa. Here, the transverse elastic coefficient of the first piezoelectric element 6 is about ⅛ times the longitudinal elastic coefficient of the base member 2. For example, the transverse elastic coefficient in the long-side direction of the first piezoelectric element 6 is defined as k1 and the longitudinal elastic coefficient of the base member 2 is defined as kb. In this case, the ratio k1/kb of the transverse elastic coefficient k1 of the first piezoelectric element 6 and the longitudinal elastic coefficient kb of the base member 2 is preferably equal to or less than 1. The ratio k1/kb may be set to be less than 0.2.

The longitudinal elastic coefficient in the thickness direction of the first piezoelectric element 6 is equal to or less than the longitudinal elastic coefficient of the base member 2.

The second piezoelectric elements 7 are formed of a material containing, for example, piezoelectric zirconate titanate. Each second piezoelectric element 7 is disposed between the tip portion 3a and the base portion 3b of the corresponding driving member 3. That is, the second piezoelectric element 7 is supported by the base portion 3b of the corresponding driving member 3 and supports the tip portion 3a on the base portion 3b. Two second piezoelectric elements 7 are disposed to be adjacent to each other in the diameter direction of the base member 2.

Each second piezoelectric element 7 has a strip-like shape which is long in the direction tangential to the central circle passing through the centers of the driving members 3, that is, in the direction tangential to the turning circle of the rotor 4 at the centers of the driving members 3 (a direction along with the circumferential direction of the base member 2 and parallel to the upper surface of the base portion 3b where the second piezoelectric elements 7 are arranged, a direction orthogonal to the shaft direction of the support shaft 5 (the second direction)). The second piezoelectric element 7 is disposed to vibrate in a thickness-shear vibration mode in the direction tangential to the central circle passing through the centers of the driving members 3, that is, in the tangential direction (the second direction) of the turning circle of the rotor 4 at the centers of the driving members 3 (a direction along with the circumferential direction of the base member 2 and parallel to the upper surface of the base portion 3b where the second piezoelectric elements 7 are arranged, a direction orthogonal to the shaft direction of the support shaft 5 (the second direction)). Each second piezoelectric element 7 is bonded to both the tip portion 3a and the base portion 3b of the corresponding driving member 3 with a conductive adhesive.

Here, the thickness direction of the second piezoelectric element 7 is defined as the direction parallel to the shaft direction of the support shaft 5. At this time, the longitudinal elastic coefficient in the thickness direction of the second piezoelectric element 7 is greater than the transverse elastic coefficient in the long-side direction thereof. For example, when the vibration mode of the second piezoelectric element 7 is a longitudinal-effect thickness-shear vibration mode, the longitudinal elastic coefficient of the second piezoelectric element 7 is about 167 GPa and the transverse elastic coefficient thereof is about 25 GPa.

That is, the transverse elastic coefficient of the second piezoelectric element 7 is about ⅙ times the longitudinal elastic coefficient.

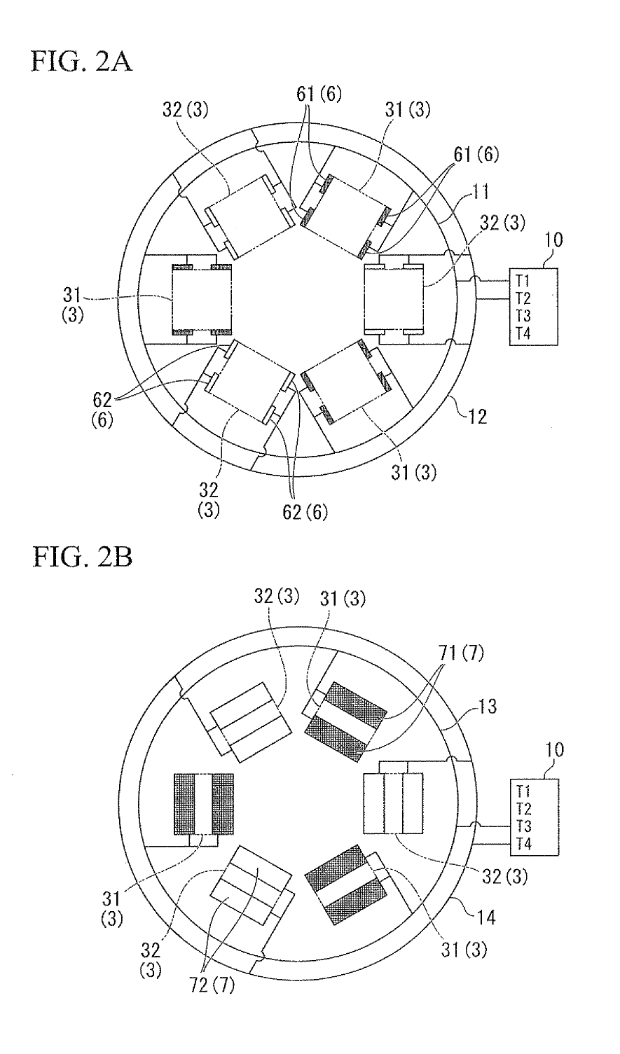

FIG. 2A is a diagram illustrating the connection state between the first piezoelectric elements and a power supply unit and FIG. 2B is a diagram illustrating the connection state between the second piezoelectric elements and the power supply unit. For purposes of ease of drawing, the second piezoelectric elements are not shown in FIG. 2A and the first piezoelectric elements are not shown in FIG. 2B.

As shown in FIGS. 2A and 2B, the driving mechanism 1 includes a power supply unit 10 supplying voltages to the first piezoelectric elements 6 and the second piezoelectric elements 7. The power supply unit 10 includes a first terminal T1, a second terminal T2, a third terminal T3, and a fourth terminal T4. The first to fourth terminals T1 to T4 supply sinusoidal voltages of a predetermined frequency. The power supply unit 10 supply voltages having a predetermined phase difference and having the same sinusoidal waveform between the first terminal T1 and the second terminal T2 and between the third terminal T3 and the fourth terminal T4.

As shown in FIGS. 1 and 2A, twelve first piezoelectric elements 61 disposed between three driving members 31 belonging to the first group and the base member 2 out of the plural first piezoelectric elements 6 are electrically connected to the first terminal T1 via a wiring 11. Twelve first piezoelectric elements 62 disposed between three driving members 32 belonging to the second group and the base member 2 out of the plural first piezoelectric elements 6 are electrically connected to the second terminal T2 via a wiring 12.

As shown in FIGS. 1 and 2B, six second piezoelectric elements 71 disposed between the tip portions 31a and the base portions 31b of three driving members 31 belonging to the first group out of the plural second piezoelectric elements 7 are electrically connected to the third terminal T3 via a wiring 13. Six second piezoelectric elements 72 disposed between the tip portions 32a and the base portions 32b of three driving members 32 belonging to the second group out of the plural second piezoelectric elements 7 are electrically connected to the fourth terminal T4 via a wiring 14.

In the driving mechanism 1, when the rotor 4 is made to rotate through the use of the driving members 3, three driving members 31 of the first group are driven synchronously. Three driving members 32 of the second group are driven synchronously with a predetermined phase difference from the three driving members 31 of the first group, similarly to three driving members 31 of the first group. Accordingly, three driving members 31 of the first group and three driving members 32 of the second group alternately support the rotor 4 and cause the rotor 4 to rotate.

Specifically, the first terminal T1 of the power supply unit 10 supplies a sinusoidal voltage to the first piezoelectric elements 61. Then, the first piezoelectric elements 61 start their thickness-shear vibration in the first direction along the support shaft 5. The driving members 31 are driven by the deformation of the first piezoelectric elements 61 and move in the direction in which they are separated from the base portion 2.

At this time, the third terminal T3 of the power supply unit 10 supplies a sinusoidal voltage to the second piezoelectric elements 71. Then, the second piezoelectric elements 71 starts their thickness-shear vibration to the front side in the rotation direction R of the rotor 4, in the direction tangential to the central circle passing through the centers of the driving members 3, that is, in the direction (the second direction) tangential to the turning circle of the rotor 4 at the centers of the driving members 3. The tip portions 31a of the driving members 31 are driven in the direction tangential to the central circle passing through the centers of the driving members 3, that is, in the second direction perpendicular to the shaft direction of the support shaft 5, by the deformation of the second piezoelectric elements 71. At this time, the tip portions 31a of the driving members 31 cause the rotor 4 to rotate forward in the rotation direction R thereof through the use of the frictional force acting between the rotor 4 and the tip portions 31a.

Thereafter, the first piezoelectric elements 61 start the deformation in the direction in which they are separated from the rotor 4 (in the reverse direction) by the sinusoidal voltage supplied from the first terminal T1 of the power supply unit 10. The driving members 31 of the first group move in the direction in which they are separated from the rotor 4 through the use of the reverse deformation of the first piezoelectric elements 61.

At this time, the second piezoelectric elements 71 start the deformation to the rear side in the rotation direction R of the rotor 4 (in the reverse direction) by the sinusoidal voltage supplied from the third terminal T3 of the power supply unit 10. The tip portions 31a of the driving members 31 of the first group move to the rear side in the rotation direction R of the rotor 4 through the use of the deformation in the reverse direction of the second piezoelectric elements 71 in the state where they are separated from the rotor 4.

Thereafter, the driving members 31 of the first group repeat the contact of the tip portions 31a with the rotor 4, the (driving) movement of the tip portions 31a to the front side in the rotation direction R of the rotor 4, the separation of the tip portions 31a from the rotor 4, and the driving of the tip portions 31a to the rear side in the rotation direction R of the rotor 4. That is, the base portions 31b and the tip portions 31a of the driving members 31 are driven by the first piezoelectric elements 61 and vibrate in the first direction substantially parallel to the shaft direction of the support shaft 5. The tip portions 31a of the driving members 31 are driven by the second piezoelectric elements 71 and vibrate in the direction tangential to the central circle passing through the centers of the driving members 3, that is, in the direction (the second direction) tangential to the turning circle of the rotor 4 at the centers of the driving members 3, relative to the base portions 31b and the base member 2. Accordingly, the driving members 31 of the first group are driven so that the tip portions 31a thereof draw a circular locus or an elliptical locus viewed from the radial direction of the base member 2.

The driving members 32 of the second group are driven with a predetermined phase difference from the driving members 31 of the first group, similarly to the driving members 31 of the first group. That is, the second terminal T2 of the power supply unit 10 supplies a sinusoidal voltage having the same waveform as the voltage supplied from the first terminal T1 and having a predetermined phase difference from the voltage supplied from the first terminal T1 to the first piezoelectric elements 62. The fourth terminal T4 of the power supply unit 10 supplies a sinusoidal voltage having the same waveform as the voltage supplied from the third terminal T3 and having a predetermined phase difference from the voltage supplied from the third terminal T3 to the second piezoelectric elements 72.

The tip portions 32a of three driving members 32 of the second group come in contact with the rotor 4 before the tip portions 31a of three driving members 31 of the first group are separated from the rotor 4, and are separated from the rotor 4 after the tip portions 31a of three driving members 31 of the first group come in contact with the rotor 4. Accordingly, the rotor 4 is alternately supported and driven by three driving members 31 of the first group and three driving members 32 of the second group, and rotate forward or backward in the rotation direction R at a predetermined rotation speed in the state where its position in the shaft direction of the support shaft 5 is kept substantially constant.

In this way, the driving mechanism 1 includes the first piezoelectric elements 6 vibrating in the thickness-shear vibration mode in the first direction parallel to the support shaft 5 and the second piezoelectric elements 7 vibrating in the thickness-shear vibration mode in the direction tangential to the central circle passing through the centers of the driving members 3, that is, in the second direction tangential to the turning circle of the rotor 4 at the centers of the driving members 3.

Accordingly, the base portion 3h and the tip portion 3a of each driving member 3 can be made to vibrate in the direction substantially parallel to the support shaft 5 relative to the base member 2 by the use of the first piezoelectric elements 6. The tip portion 3a of each driving member 3 can be made to vibrate in the direction tangential to the central circle passing through the centers of the driving members 3, that is, in the direction tangential to the turning circle of the rotor 4 at the centers of the driving members 3, relative to the base member 2 and the base portion 3b of the driving member 3 by the use of the second piezoelectric elements 7.

Therefore, in the driving mechanism 1 according to this embodiment, it is possible to independently control the vibration of the tip portions 3a of the driving members 3 in the direction substantially parallel to the support shaft 5 and the vibration of the tip portions 3a in the direction tangential to the turning circle of the rotor 4 at the centers of the driving members 3 by independently controlling the first piezoelectric elements 6 and the second piezoelectric elements 7. Accordingly, compared with the configuration disclosed in JP-A-2007-236138, it is possible to cause the driving members 3 to efficiently vibrate in the respective directions and to cause the rotor 4 to efficiently rotate.

In the driving mechanism 1, the first electric elements 6 vibrate in the thickness-shear vibration mode in the direction parallel to the support shaft 5, which is a direction in which the base portions 3b of the driving members 3 are driven. That is, in the first piezoelectric elements 6, the longitudinal elastic coefficient indicating the stiffness in the thickness direction is greater than the transverse elastic coefficient indicating the stiffness in the vibration direction. In other words, in the first piezoelectric elements 6, the stiffness in the direction in which the base portion 3b of each driving member 3 vibrates is relatively small and the stiffness in the direction perpendicular to the direction in which the base portion 3b of the driving member 3 vibrates is relatively great.

In the driving mechanism 1, the tip portions 3a vibrate in the direction tangential to the turning circle of the rotor 4 at the centers of the driving members 3, which is the direction perpendicular to the direction in which the base portions 3b vibrate, on the base portions 3b of the driving members 3. However, in the first piezoelectric elements 6, the stiffness in the direction in which the base portion 3b of each driving member 3 vibrates is relatively small and the stiffness in the vibration direction of the tip portion 3a which is the direction perpendicular to the direction in which the base portion 3b of the driving member 3 vibrates is relatively great. The first piezoelectric elements 6 are arranged to interpose the base portion 3b of each driving member 3 between both sides in the vibration direction of the tip portion 3a. Accordingly, the sufficient resistance to the inertial force due to the vibration of the tip portion 3a of the driving member 3 acts from the first piezoelectric elements 6 to the base portion 3b of the driving member 3. Accordingly, even when the tip portion 3a of each driving member 3 vibrates in the direction tangential to the turning circle of the rotor 4 at the centers of the driving members 3, the base portion 3b is not difficult to vibrate in the direction well.

In the driving mechanism 1, the second piezoelectric elements 7 vibrate in the thickness-shear vibration mode in the direction which is perpendicular to the support shaft 5 and which is the direction in which the tip portion 3a of each driving member 3 is driven. That is, in the second piezoelectric elements 7, the longitudinal elastic coefficient indicating the stiffness in the thickness direction is greater than the transverse elastic coefficient indicating the stiffness in the vibration direction. In other words, in the second piezoelectric elements 7, the stiffness in the direction in which the tip portion 3a of the driving member 3 vibrates is relatively small and the stiffness in the direction in which the base portion 3b of the driving member 3 vibrates is relatively great. Accordingly, the tip portion 3a of the driving member 3 vibrates integrally with the base portion 3b in the vibration direction, which is parallel to the shaft direction of the support shaft 5, due to the first piezoelectric elements 6. On the other hand, the tip portion 3a of the driving member 3 vibrates independently of the base portion 3b in the vibration direction, which is parallel to the direction tangential to the turning circle of the rotor 4 at the centers of the driving members 3, due to the second piezoelectric elements 7.

Therefore, in the driving mechanism 1 according to this embodiment, it is possible to prevent the vibration of the base portion 3b of each driving members 3 from interfering with the vibration in the direction perpendicular to the vibration direction. It is also possible to prevent the vibration of the tip portion 3a of each driving member 3 from interfering with the vibration in the direction perpendicular to the vibration direction. As a result, it is possible to independently control the vibration of the tip portion 3a of each driving member 3 in the direction parallel to the support shaft 5 and the vibration of the tip portion 3a of the driving member 3 in the direction perpendicular to the support shaft 5.

In the driving mechanism 1, the longitudinal elastic coefficient of the first piezoelectric elements 6 is greater than the longitudinal elastic coefficient of the base member 2. Accordingly, it is possible to cause the sufficient resistance relative to the inertial force, which acts on the base portion 2 via the first piezoelectric element 6, due to the vibration of the tip portion 3a of each driving member 3 to be applied by the use of the inner faces of the corresponding holding portion 2a of the base member 2. Therefore, it is possible to prevent the base portion 3b of the driving member 3 from vibrating in the vibration direction of the tip portion 3a. The longitudinal elastic coefficient of the first piezoelectric elements 6 may be equal to the longitudinal elastic coefficient of the base member 2.

Here, it is assumed that the ratio k1/kb of the transverse elastic coefficient k1 of the first piezoelectric elements 6 and the longitudinal elastic coefficient kb of the base member 2 is equal to or greater than 0.2. Then, the difference between the stiffness of the first piezoelectric elements 6 in the vibration direction of the base portion 3b of the driving member 3 and the stiffness of the first piezoelectric elements 6 in the direction perpendicular to the vibration direction may not be sufficient. In this case, the vibration of the base portion 3b of the driving member 3 in the direction parallel to the shaft direction of the support shaft 5 may interfere with the vibration of the tip portion 3a of the driving member 3 parallel to the direction tangential to the turning circle of the rotor 4 at the centers of the driving members 3, thereby not independently controlling the vibrations.

In the driving mechanism 1 according to the present embodiment, the ratio k1/kb is less than 0.2. Therefore, the difference between the stiffness of the first piezoelectric elements 6 in the vibration direction of the base portion 3b of the driving member 3 and the stiffness of the first piezoelectric elements 6 in the direction perpendicular to the vibration direction may not be sufficient, then the vibration of the base portion 3b of the driving member 3 in the direction parallel to the shaft direction of the support shaft 5 and the vibration of the tip portion 3a of the driving member 3 parallel to the direction tangential to the turning circle of the rotor 4 at the centers of the driving members 3 can be made to be independent of each other, thereby independently controlling the vibrations.

As described above, in the driving mechanism 1 according to this embodiment, it is possible to independently control the vibrations in two different directions of the base portion 3b and the tip portion 3a of the driving member 3 which is driven by the first piezoelectric elements 6 and the second piezoelectric elements 7. It is possible to cause the base portion 3b and the tip portion 3a of the driving member 3, which is driven by the first piezoelectric elements 6 and the second piezoelectric elements 7, to efficiently vibrate in two different directions.

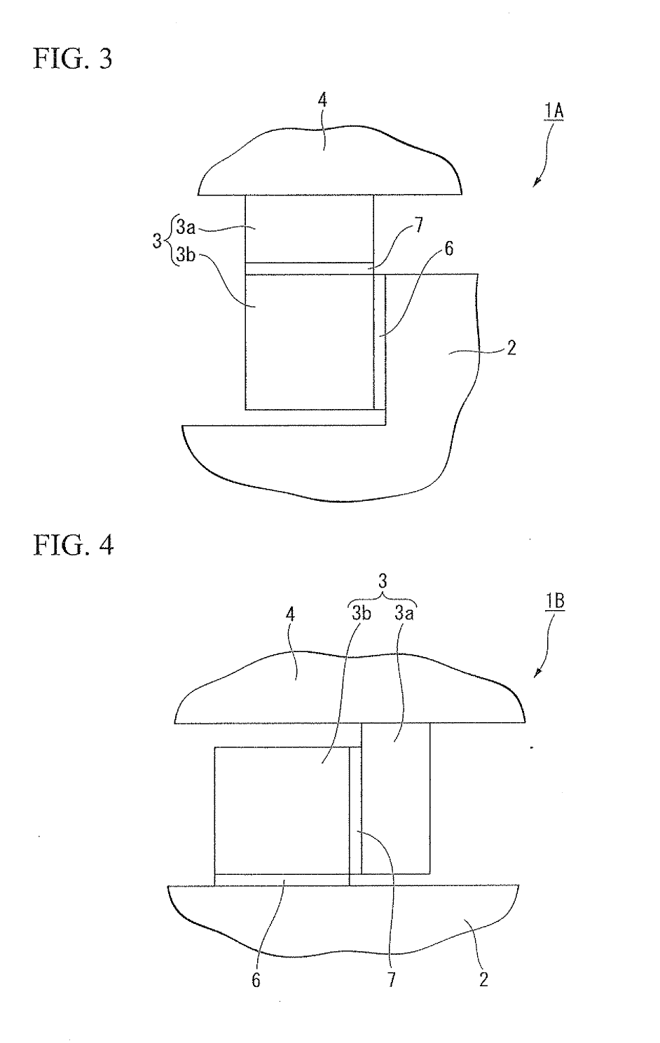

Modifications of the driving mechanism 1 according to this embodiment will be described below incorporating FIG. 1, FIGS. 2A and 2B, and referring to FIGS. 3 and 4.

As shown in FIG. 3, in a driving mechanism 1A which is a first modification of the driving mechanism 1, the first piezoelectric elements 6 are disposed only between one side face of the base portion 3b of each driving member 3 and the base member 2. The other configuration is the same as the driving mechanism 1.

According to the driving mechanism 1A, similarly to the driving mechanism 1, it is possible to efficiently drive the tip portion 3a of each driving member 3 in a circular locus or an elliptical locus viewed from the radial direction of the base member 2. Therefore, according to the driving mechanism 1A, it is possible to achieve the same advantages as the driving mechanism 1 and to reduce the number of the first piezoelectric elements 6, thereby simplifying the configuration.

As shown in FIG. 4, in a driving mechanism 1B which is a second modification of the driving mechanism 1, the bottom surface of the base portion 3b of each driving member 3 is fixed to the base member 2 via the first piezoelectric elements 6. The tip portion 3a is fixed to one side face of the base portion 3b of each driving member 3 via the second piezoelectric elements 7. The other configuration is the same as the driving mechanism 1.

In the driving mechanism 1B, the first piezoelectric elements 6 vibrate in the thickness-shear vibration mode in the direction tangential to the central circle passing through the centers of the driving members 3, that is, in the direction (the second direction) tangential to the turning circle of the rotor 4 at the centers of the driving members 3. Accordingly, the base portion 3b and the tip portion 3a of each driving member 3 are driven by the first piezoelectric elements 6 and vibrate in the direction tangential to the turning circle of the rotor 4 at the centers of the driving members 3.

The second piezoelectric elements 7 are supported by the side face of the base portion 3b of each driving member 3 and vibrate in the thickness-shear vibration mode in the direction (the first direction) parallel to the shaft direction of the support shaft 5. The tip portion 3a of the driving member 3 is driven by the second piezoelectric elements 7 and vibrates in the direction parallel to the shaft direction of the support shaft 5.

Therefore, according to the driving mechanism 1B, similarly to the driving mechanism 1, it is possible to efficiently drive the tip portion 3a of each driving member 3 in a circular locus or an elliptical locus viewed from the radial direction of the base member 2. Therefore, according to the driving mechanism 1B, it is possible to achieve the same advantages as the driving mechanism 1 and to reduce the number of the first piezoelectric elements 6, thereby simplifying the configuration.

A second embodiment of the invention will be described below with reference to the accompanying drawings. In the following description, the elements equal to or equivalent to those of the above-mentioned embodiment are referenced by like reference signs and the description thereof is made in brief or is not repeated.

A driving mechanism according to this embodiment performs a relative driving operation of displacing a rotor relative to a base member and drives an optical device or an electronic device such as a lens barrel of a camera through the use of the rotor.

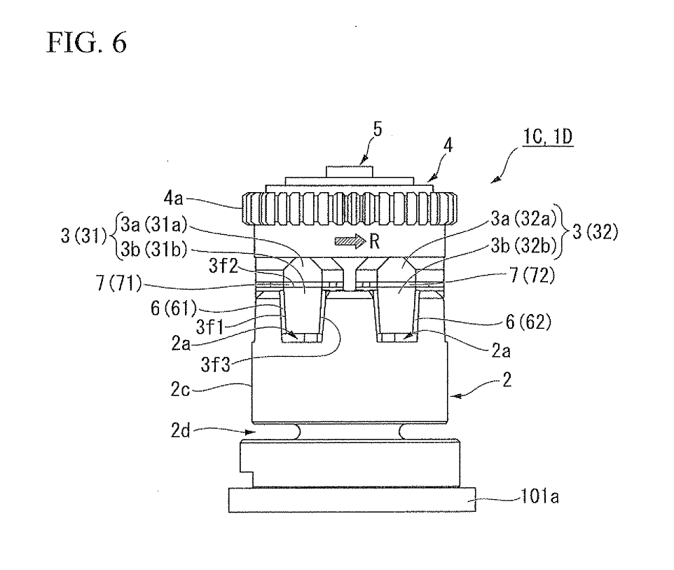

FIG. 6 is a front view of the driving mechanism 1C according to this embodiment.

As shown in FIG. 6, a driving mechanism 1C includes a base member 2, driving members 3, a rotor 4, a support shaft 5, first piezoelectric elements 6 vibrating in a thickness-shear vibration mode in a first direction, and second piezoelectric elements 7 vibrating in the thickness-shear vibration mode in a second direction different from the first direction.

The base member 2 is a conductive elastic body and is formed of a material containing stainless steel. The base member 2 has a hollow cylindrical shape having a through-hole in the shaft direction at the center thereof. The surface of the base member 2 is subjected to insulating treatment, for example, by forming an insulating film (not shown) thereon. The support shaft 5 is inserted into the through-hole of the base member 2.

Plural holding portions 2a are formed at one end (top end) of the base member 2 so as to be adjacent to each other in the circumferential direction of the base member 2. Each holding portion 2a has a concave shape. The holding portion 2a supports the corresponding driving member 3 with the driving member 3 interposed between both sides in the circumferential direction of the base member 2.

The other end (bottom end) of the base member 2 is fixed to a mounting section 101a through the use of fastening members (not shown) such as bolts. A groove portion 2d which is continuous in the circumferential direction is formed in the part of the base member 2 closer to the mounting section 101a than the center.

The driving mechanism 1C includes two groups of which each includes three driving members 3 and which are driven with a predetermined phase difference. In this embodiment, out of six driving members 3 arranged at an equal interval in the circumferential direction of the base member 2, three driving members 31 belong to the first group and three driving members 32 belong to the second group. The driving members 31 of the first group and the driving members 32 of the second group are alternately arranged in the circumferential direction of the base member 2, that is, in the rotation direction R of the rotor 4.

Each driving member 3 includes a base portion (the first member) 3b and a tip portion (the second member) 3a.

The base portion 3b is conductive and is formed of, for example, light metal alloy. The base portion 3b has a substantially rectangular parallelepiped shape of which a pair of side faces intersecting the circumferential direction of the base member 2 is slightly inclined. The base portion 3b is supported by the corresponding holding portion 2a so as to be movable in a direction parallel to the support shaft 5. The base portion 3b is driven by the first piezoelectric elements 6 and vibrates in the first direction.

The base portion 3b supports the first piezoelectric elements 6 on a first face 311 (the side face) parallel to the first direction and supports the second piezoelectric elements 7 on a second face 3f2 (the surface) parallel to the second direction. The first face 3f1 and the second face 3f2 intersect each other at an acute angle. The angle formed by the first face 3f1 and the second face 3f2 is set, for example, to be equal to or greater than 84° and equal to or less than 88°, in view of the sizes and tolerance of the members.

Plural (four) first piezoelectric elements 6 are disposed in the base portion 3b. The base portion 3b supports two first piezoelectric elements 6 out of four first piezoelectric elements on the first face 3f1 and supports the other two first piezoelectric elements 6 on a third face (the side face) 3f3 opposed to the first face 3f1. The third face 3f3 and the second face 3f2 intersect each other at an acute angle. The angle formed by the third face 3f3 and the second face 3f2 is equal to the angle formed by the first face 3f1 and the second face 3f2.

The tip portion 3a is conductive and is formed of, for example, stainless steel. The tip portion 3a has a hexagonal prism shape having a mountain-like cross-section viewed from the radial direction of the base member 2. The tip portion 3a is disposed between the base portion 3b and the rotor 4. The tip portion 3a protrudes from the corresponding holding portion 2a to support the rotor 4. The tip portion 3a is driven by the second piezoelectric elements 7 and vibrates in the second direction.

The rotor 4 is mounted on the support shaft 5 via bearings (not shown). The rotor 4 is disposed to be rotatable forward and backward in the rotation direction R about the support shaft 5. A gear 4a used to drive, for example, a lens barrel of a camera or the like is formed on the outer circumferential surface of the rotor 4. The face of the rotor 4 facing the base member 2 is supported by plural driving members 3.

The support shaft 5 is a circular rod-like member of which the center line corresponds to the rotation shaft of the rotor 4. One end (bottom end) of the support shaft 5 is fixed to the mounting section 101a. The support shaft 5 passes through the base member 2 and the rotor 4. The support shaft 5 is disposed at the center of the plural driving members 3 arranged in the rotation direction R of the rotor 4.

The first piezoelectric elements 6 are fanned of a material containing, for example, piezoelectric zirconate titanate (PZT). The first piezoelectric elements 6 are disposed between the inner face of the corresponding holding portion 2a of the base member 2 and the side faces of the base portion 3b of the corresponding driving member 3. The first piezoelectric elements 6 are disposed to interpose the base portion 3b of the driving member 3 between the front side and the rear side in the rotation direction R of the rotor 4.

Each first piezoelectric element 6 is formed to be long in the shaft direction of the support shaft 5. Plural (two) first piezoelectric elements 6 vibrate in the thickness-shear vibration mode in the first direction along the side faces 3f1 and 3f3 of the base portion 3b. The first piezoelectric elements 6 are disposed to vibrate in the thickness-shear vibration mode in the long-side direction substantially parallel to the shaft direction of the support shaft 5. Each first piezoelectric element 6 is bonded to both the inner face of the corresponding holding portion 2a of the base member 2 and the side faces 3f1 and 3f3 of the base portion 3b of the corresponding driving member 3 with a conductive adhesive.

Each second piezoelectric element 7 is formed of a material containing, for example, piezoelectric zirconate titanate (PZT). Each second piezoelectric element 7 is formed to be long in the direction tangential to the central circle passing through the centers of the driving members 3, that is, in the direction tangential to the turning circle of the rotor 4 at the centers of the driving members 3. The second piezoelectric element 7 vibrates in the thickness-shear vibration mode in the second direction along the surface 3f2 of the base portion 3b. The second piezoelectric elements 7 are disposed to vibrate in the thickness-shear vibration mode in the direction tangential to the central circle passing through the centers of the driving members 3. That is, the second piezoelectric elements 7 are disposed to vibrate in the thickness-shear vibration mode in the direction tangential to the turning circle of the rotor 4 at the centers of the driving members 3. Each second piezoelectric element 7 is bonded to both the bottom surface of the tip portion 3a and the surface 3f2 of the base portion 3b of the corresponding driving member 3 with a conductive adhesive.

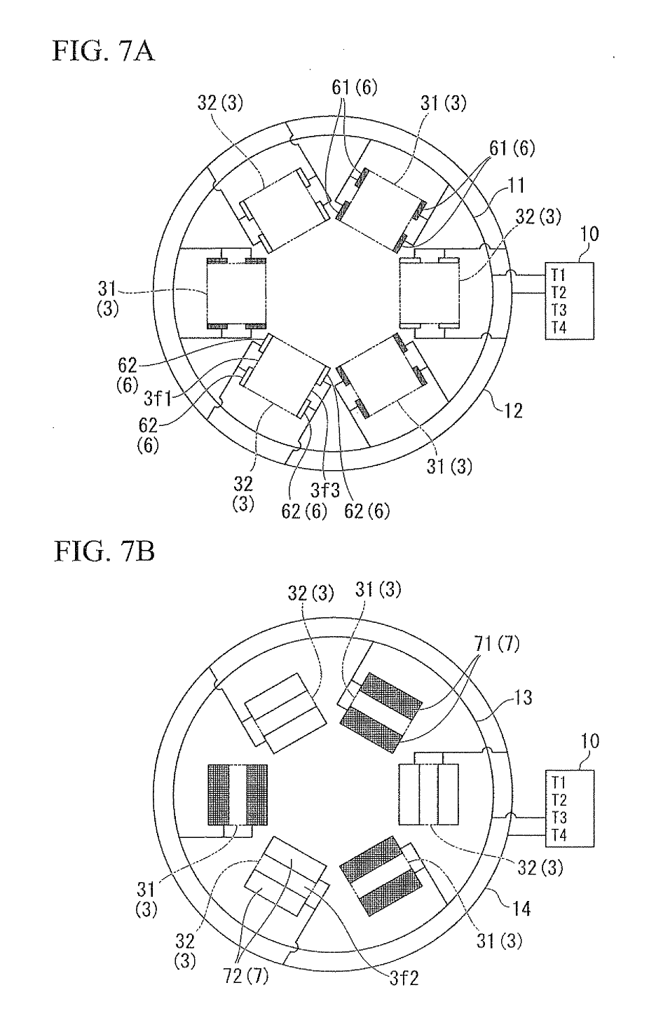

FIGS. 7A and 713 are circuit diagrams of the driving mechanism shown in FIG. 6. FIG. 7A is a diagram illustrating the connection state between the first piezoelectric elements and a power supply unit and FIG. 7B is a diagram illustrating the connection state between the second piezoelectric elements and the power supply unit. For purposes of ease of drawing, the second piezoelectric elements are not shown in FIG. 7A and the first piezoelectric elements are not shown in FIG. 7B.

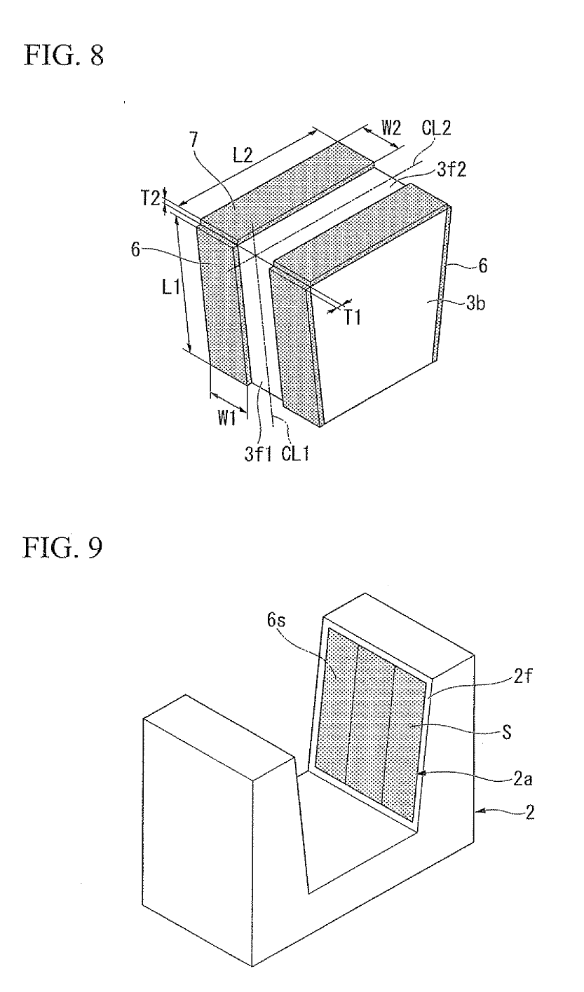

FIG. 8 is a perspective view illustrating an arrangement state of the piezoelectric elements of the driving mechanism 1C shown in FIG. 6. In FIG. 8, reference sign CL1 represents a first center line passing through the center of the first face 3f1 and being parallel to the first direction and reference sign CL2 represents a second center line passing through the center of the second face 3f2 and being parallel to the second direction. Reference sign L1 represents the length in the long-side direction of the first piezoelectric element 6, reference sign W1 represents the length (width) in the short-side direction of the first piezoelectric element 6, and reference sign T1 represents the thickness (the distance between the first face 3f1 of the base portion 3b and the surface of the first piezoelectric element 6) of the first piezoelectric element 6. Reference sign L2 represents the length in the long-side direction of the second piezoelectric element 7, reference sign W2 represents the length (width) in the short-side direction of the second piezoelectric element 7, and reference sign T2 represents the thickness (the distance between the second face 3f2 of the base portion 3b and the surface of the second piezoelectric element 7) of the second piezoelectric element 7.

For example, when the piezoelectric elements 6 and 7 are of a stacked type (an element in which a piezoelectric body is interposed between two electrodes), the piezoelectric elements 6 and 7 are parts in which the upper electrode, the piezoelectric body, and the lower electrode overlap with each other in a plan view. That is, the length in the long-side direction of the piezoelectric elements 6 and 7 is defined as the length of the part in which the upper electrode, the piezoelectric body, and the lower electrode overlap with each other in the long-side direction in a plan view. The length in the short-side direction of the piezoelectric elements 6 and 7 is defined as the length of the part in which the upper electrode, the piezoelectric body, and the lower electrode overlap with each other in the short-side direction in a plan view.

As shown in FIG. 8, plural (two) first piezoelectric elements 6 which have the long-side in the first direction are disposed as the first piezoelectric elements 6 on the first face 3f1 with a gap interposed therebetween in the short-side direction of the first piezoelectric elements 6. Accordingly, it is possible to stably obtain (acquire) the vibration (main vibration) of the first piezoelectric elements 6 in the first direction, compared with the configuration in which the first piezoelectric element is formed on the entire surface of the first face.

For example, when the first piezoelectric element is formed on the entire surface of the first face, the undesired vibration (the vibration in the direction perpendicular to the first direction) other than the main vibration of the first piezoelectric element increases. Then, the main vibration and the undesired vibration resonate with the same frequency, thereby causing a surface resonance vibration state. That is, the vibration energy in the main vibration direction is divided into two directions of the main vibration direction and the undesired vibration direction and is dissipated. However, in this embodiment, since the first piezoelectric element 6 has the long-side in the first direction, the undesired vibration hardly occurs. Accordingly, it is easy to obtain the vibration (main vibration) of the first piezoelectric elements 6 in the first direction. Since the first piezoelectric elements 6 are disposed with a gap in the short-side direction, the undesired vibration occurring in one first piezoelectric element 6 is hardly transmitted to the other first piezoelectric element 6. Therefore, it is possible to stably obtain the vibration of the first piezoelectric elements 6 in the first direction. As a result, it is possible to independently control the vibrations in two different directions of the member which is driven by the piezoelectric elements 6 and 7 and thus to provide a driving mechanism 1C which can stably drive the member which is driven by the piezoelectric elements 6 and 7.

Plural first piezoelectric elements 6 are disposed on both right and left sides of the first center line CL1. Accordingly, compared with the configuration in which plural first piezoelectric elements are disposed on one side of the right and left sides of the first center line, it is possible to stably obtain the vibration (main vibration) of the first piezoelectric elements 6 in the first direction.

For example, when plural first piezoelectric elements are disposed on one side of the right and left sides of the first center line, the undesired vibration (the vibration in the direction perpendicular to the first direction) of the first piezoelectric elements is concentrated on only one side of the right and left sides of the first face of the base portion. Accordingly, the stiffness of the base portion against the undesired vibration decreases (the base portion can be easily deformed by the undesired vibration), thereby making it difficult to stably obtain the vibration of the first piezoelectric elements in the first direction. However, in this embodiment, since the plural first piezoelectric elements 6 are disposed on both right and left sides of the first center line CL1, the stiffness of the base portion 3b against the undesired vibration increases. Therefore, it is possible to stably obtain the vibration of the first piezoelectric elements 6 in the first direction.

The plural first piezoelectric elements 6 are disposed to be linearly symmetric about the first center line CL1.

Accordingly, compared with the configuration in which plural first piezoelectric elements are disposed to be asymmetric about the first center line, the stiffness of the base portion 3b against the undesired vibration increases. Therefore, it is possible to stably obtain the vibration of the first piezoelectric elements 6 in the first direction.

The plural first piezoelectric elements 6 are formed in contact with the edge of the first face 3f1 in the direction perpendicular to the first direction (the first center line CL1). Accordingly, in the configuration in which plural first piezoelectric elements are formed with a gap from the edge of the first face in the direction perpendicular to the first direction, the gap between the plural first piezoelectric elements 6 in the short-side direction increases. That is, the undesired vibration occurring in one first piezoelectric element 6 is hardly transmitted to the other first piezoelectric element 6. Therefore, it is possible to stably obtain the vibration of the first piezoelectric elements 6 in the first direction.

The length L1 in the long-side direction of the first piezoelectric elements 6 is set to be equal to or greater than three times the length W1 in the short-side direction of the first piezoelectric elements 6 and equal to or less than 100 times the length W1. Accordingly, it is possible to stably obtain the vibration (main vibration) of the first piezoelectric elements 6 in the first direction. On the other hand, when the length L1 of the long-side direction of the first piezoelectric elements 6 is smaller than three times the length W1 in the short-side direction of the first piezoelectric elements 6, the undesired vibration increases, thereby making it difficult to stably obtain the main vibration. When the length L1 in the long-side direction of the first piezoelectric elements 6 is greater than 100 times the length W1 in the short-side direction of the first piezoelectric elements 6, it is difficult to form the first piezoelectric elements 6.

The thickness T1 of the first piezoelectric elements 6 is set to be equal to or greater than 1/100 times the length W1 in the short-side direction of the first piezoelectric elements 6 and equal to or less than ⅓ times the length W1. Accordingly, it is possible to stably obtain the vibration (main vibration) of the first piezoelectric elements 6 in the first direction. On the other hand, when the thickness T1 of the first piezoelectric elements 6 is greater than ⅓ times the length W1 in the short-side direction of the first piezoelectric elements 6, a vibration (thickness vibration) occurs in the thickness direction of the first piezoelectric elements 6. That is, the undesired vibration increases, thereby making it difficult to stably obtain the main vibration. When the thickness T1 of the first piezoelectric elements 6 is smaller than 1/100 times the length W1 in the short-side direction of the first piezoelectric elements 6, it is difficult to form the first piezoelectric elements 6.

Plural (two) second piezoelectric elements 7 which have the long-side in the second direction are disposed as the second piezoelectric elements 7 on the second face 3f2 with a gap interposed therebetween in the short-side direction of the second piezoelectric elements 7. Accordingly, it is possible to stably obtain the vibration (main vibration) of the second piezoelectric elements 7 in the second direction, compared with the configuration in which the second piezoelectric element is formed on the entire surface of the second face.

For example, when the second piezoelectric element is formed on the entire surface of the second face, the undesired vibration (the vibration in the direction perpendicular to the second direction) other than the main vibration of the second piezoelectric element increases. Then, the main vibration and the undesired vibration resonate with the same frequency, thereby causing a surface resonance vibration state. That is, the vibration energy in the main vibration direction is divided into two directions of the main vibration direction and the undesired vibration direction and is dissipated. However, in this embodiment, since the second piezoelectric element 7 has a long-side in the second direction, the undesired vibration hardly occurs. Accordingly, it is easy to obtain the vibration (main vibration) of the second piezoelectric elements 7 in the second direction. Since the second piezoelectric elements 7 are disposed with a gap in the short-side direction, the undesired vibration occurring in one second piezoelectric element 7 is hardly transmitted to the other second piezoelectric element 7. Therefore, it is possible to stably obtain the vibration of the second piezoelectric elements 7 in the second direction.

Plural second piezoelectric elements 7 are disposed on both right and left sides of the second center line CL2. Accordingly, compared with the configuration in which plural second piezoelectric elements are disposed on one side of the right and left sides of the second center line, it is possible to stably obtain the vibration (main vibration) of the second piezoelectric elements 7 in the second direction.

For example, when plural second piezoelectric elements are disposed on one side of the right and left sides of the second center line, the undesired vibration (the vibration in the direction perpendicular to the second direction) of the second piezoelectric elements is concentrated on only one side of the right and left sides of the second face of the base portion. Accordingly, the stiffness of the base portion against the undesired vibration decreases (the base portion can be easily deformed by the undesired vibration), thereby making it difficult to stably obtain the vibration of the second piezoelectric elements in the second direction. However, in this embodiment, since the plural second piezoelectric elements 7 are disposed on both right and left sides of the second center line CL2, the stiffness of the base portion 3b against the undesired vibration increases. Therefore, it is possible to stably obtain the vibration of the second piezoelectric elements 7 in the second direction.

The plural second piezoelectric elements 7 are disposed to be linearly symmetric about the second center line CL2.

Accordingly, compared with the configuration in which plural second piezoelectric elements are disposed to be asymmetric about the second center line, the stiffness of the base portion 3b against the undesired vibration increases. Therefore, it is possible to stably obtain the vibration of the second piezoelectric elements 7 in the second direction.

The plural second piezoelectric elements 7 are formed in contact with the edge of the second face 3f2 in the direction perpendicular to the second direction (the second center line CL2). Accordingly, in the configuration in which plural second piezoelectric elements are formed with a gap from the edge of the second face in the direction perpendicular to the second direction, the gap between the plural second piezoelectric elements 7 in the short-side direction increases. That is, the undesired vibration occurring in one second piezoelectric element 7 is hardly transmitted to the other second piezoelectric element 7. Therefore, it is possible to stably obtain the vibration of the second piezoelectric elements 7 in the second direction.

The length L2 in the long-side direction of the second piezoelectric elements 7 is set to be equal to or greater than three times the length W2 in the short-side direction of the second piezoelectric elements 7 and equal to or less than 100 times the length W2. Accordingly, it is possible to stably obtain the vibration (main vibration) of the second piezoelectric elements 7 in the second direction. On the other hand, when the length L2 of the long-side direction of the second piezoelectric elements 7 is smaller than three times the length W2 in the short-side direction of the second piezoelectric elements 7, the undesired vibration increases, thereby making it difficult to stably obtain the main vibration. When the length L2 in the long-side direction of the second piezoelectric elements 7 is greater than 100 times the length W2 in the short-side direction of the second piezoelectric elements 7, it is difficult to form the second piezoelectric elements 7.

The thickness T2 of the second piezoelectric elements 7 is set to be equal to or greater than 1/100 times the length W2 in the short-side direction of the second piezoelectric elements 7 and equal to or less than ⅓ times the length W2. Accordingly, it is possible to stably obtain the vibration (main vibration) of the second piezoelectric elements 7 in the second direction. On the other hand, when the thickness T2 of the second piezoelectric elements 7 is greater than ⅓ times the length W2 in the short-side direction of the second piezoelectric elements 7, a vibration (thickness vibration) occurs in the thickness direction of the second piezoelectric elements 7. That is, the undesired vibration increases, thereby making it difficult to stably obtain the main vibration. When the thickness T2 of the second piezoelectric elements 7 is smaller than 1/100 times the length W2 in the short-side direction of the second piezoelectric elements 7, it is difficult to form the second piezoelectric elements 7.

FIG. 9 is a perspective view of the base member of the driving mechanism 1C shown in FIG. 6. In FIG. 9, for purposes of ease of drawing, a partial configuration (the holding portion 2a supporting and interposing one driving member 3 of plural driving members 3 with the support faces 2f) of the base member 2 is shown. In FIG. 9, reference sign S represents an area (rectangular region) having an outline circumscribing the plural first piezoelectric elements 6 in contact with the support face 2f of the base member 2. Reference sign 6s represents a projection area of each first piezoelectric element 6 onto the support face 2f.

As shown in FIG. 9, the base member 2 supports the base portion 3b on the support faces 2f with the plural first piezoelectric elements 6 interposed therebetween. Specifically, the base member 2 supports the base portion 3b on the support faces 2f so as to interpose both the first piezoelectric element 6 disposed on the first face 3f1 and the first piezoelectric element 6 disposed on the third face 3f3 therebetween.

The area S having the outline circumscribing the plural first piezoelectric elements 6 in contact with the support face 2f of the base member 2 is square. Specifically, the rectangular shape circumscribing the projection area 6s of two first piezoelectric elements 6 onto the support face 2f is square. Accordingly, compared with the configuration in which the area having the outline circumscribing the plural first piezoelectric elements in contact with the support face of the base member is trapezoid or diamond-shaped, it is possible to stably obtain the vibration (main vibration) of the first piezoelectric elements 6 in the first direction.

For example, when the area having the outline circumscribing the plural first piezoelectric elements in contact with the support face of the base member is trapezoid, the undesired vibration (the vibration in the direction perpendicular to the first direction) of the first piezoelectric elements is concentrated on the upper part (the upper bottom) of the first face. Accordingly, the stiffness of the base portion against the undesired vibration decreases (the base portion can be easily deformed due to the undesired vibration), thereby making it difficult to stably obtain the vibration of the first piezoelectric elements in the first direction. However, in this embodiment, since the area S having the outline circumscribing the plural first piezoelectric elements 6 in contact with the support face 2f of the base member 2 is square, the stiffness of the base portion 3b against the undesired vibration increases. Therefore, it is possible to stably obtain the vibration of the first piezoelectric elements 6 in the first direction.

In this embodiment, the driving mechanism 1C includes two groups of which each has three driving members 3 and which are driven with a predetermined phase difference, but the invention is not limited to this configuration. For example, the driving mechanism 1C may include three or more groups of which each has two or four or more driving members and which move with the predetermined phase difference. That is, the number of driving members to be disposed can be appropriately changed as needed.

In this embodiment, plural (four) first piezoelectric elements 6 are disposed in the base portion 3b, but the invention is not limited to this configuration. For example, one, two, three or five or more first piezoelectric elements may be disposed in the base portion 3b. That is, the number of first piezoelectric elements to be disposed can be appropriately changed as needed.

In this embodiment, two second piezoelectric elements 7 are disposed in the base portion 3b, but the invention is not limited to this configuration. For example, one or three or more second piezoelectric elements may be disposed in the base portion 3b. That is, the number of second piezoelectric elements to be disposed can be appropriately changed as needed.

A third embodiment of the invention will be described below with reference to the accompanying drawings. In the following description, the elements equal to or equivalent to those of the above-mentioned embodiment are referenced by like reference signs and the description thereof is made in brief or is not repeated.

A driving mechanism according to this embodiment performs a relative driving operation of displacing a rotor relative to a base member and drives an optical device or an electronic device such as a lens barrel of a camera through the use of the rotor.

FIG. 6 is a front view of the driving mechanism 1D according to this embodiment.

As shown in FIG. 6, a driving mechanism 1D includes a base member 2, driving members 3, a rotor 4, a support shaft 5, first piezoelectric elements 6 vibrating in a thickness-shear vibration mode in a first direction, and second piezoelectric elements 7 vibrating in the thickness-shear vibration mode in a second direction different from the first direction.

In the present embodiment, the mass of the base portion 3b is set to be equal to the mass of the tip portion 3a. Here, the volume of the base portion 3b is defined as V1 and the volume of the tip portion 3a is defined as V2. The density of the base portion 3b is defined as ρ1 and the density of the tip portion 3a is defined as ρ2. At this time, in the driving mechanism 1D, the volume V1 of the base portion 3b, the volume V2 of the tip portion 3a, the density ρ1 of the base portion 3b, and the density ρ2 of the tip portion 3a are determined to satisfy Expression 1.

ρ1·V1=ρ2·V2 (1)

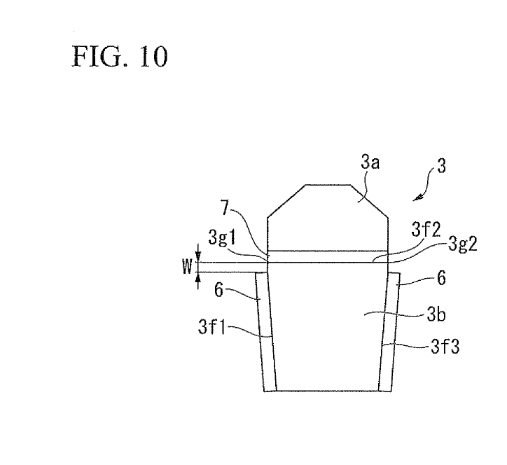

FIG. 10 is a front view of a driving member of the driving mechanism 1D shown in FIG. 6. In FIG. 10, reference sign W represents the distance between the first piezoelectric element 6 and a boundary 3g1 (3g2) between the first face 3f1 (the third face 3f3) and the second face 3f2.

As shown in FIG. 10, the first piezoelectric element 6 and the second piezoelectric element 7 are separated from each other. For example, when the piezoelectric elements 6 and 7 are of a stacked type, it is assumed that the lower electrodes as a common electrode are separated from each other.

Specifically, the first piezoelectric element 6 disposed on the first face 3f1 is separated by the distance W from a first boundary 3g1 between the first face 3f1 and the second face 3f2. The first piezoelectric element 6 disposed on the third face 3f3 is separated by the distance W from a second boundary 3g2 between the third face 3f3 and the second face 3f2. The second piezoelectric element 7 is formed in contact with the first boundary 3g1 (the edge of the second face 3f2 close to the first face 3f1) and in contact with the second boundary 3g2 (the edge of the second face 3f2 close to the third face 3f3).

The distance W between the first piezoelectric elements 6 and the boundaries 3g1 and 3g2 is set to be equal to or greater than ½ times and equal to or less than ⅔ times the thickness (the distance between the side face of the base portion 3b and the surface of the first piezoelectric element 6) of the first piezoelectric elements 6. Accordingly, it is possible to suppress the fatigue failure of the base portion 3b due to the concentration of stress on the base portion 3b (particularly, the corner interposed between the first piezoelectric element 6 and the second piezoelectric element 7) when at least one of the first piezoelectric element 6 and the second piezoelectric element 7 vibrates. On the other hand, when the distance W is smaller than ½ times the thickness of the first piezoelectric element 6, it is difficult to alleviate the concentration of stress on the base portion 3b to suppress the fatigue failure of the base portion 3b. When the distance W is greater than ⅔ times the thickness of the first piezoelectric element 6, it is difficult to stably drive the rotor 4.

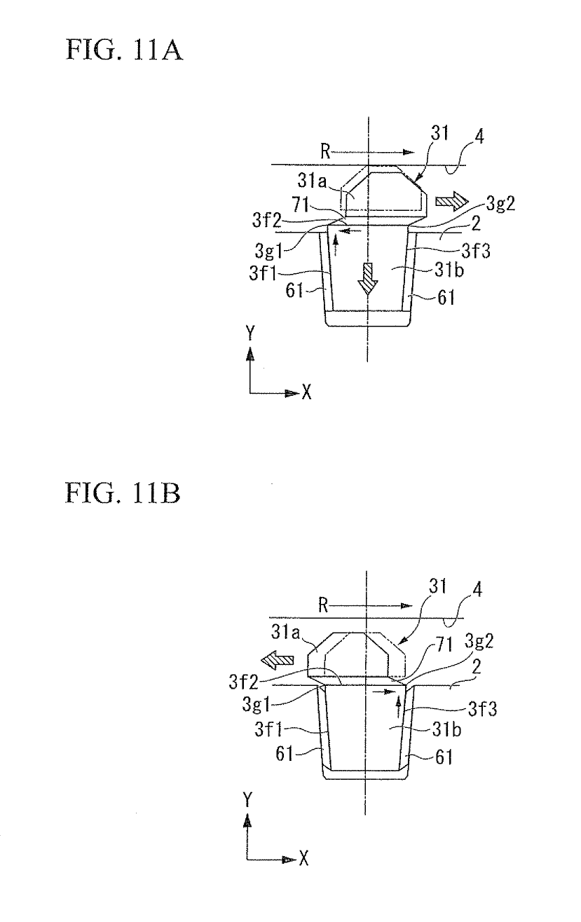

FIGS. 11A and 11B are front views illustrating the operation of a driving member of the driving mechanism 1D shown in FIG. 6. FIG. 11A is a diagram illustrating a state (Phase 1) in which the tip portion 31a moves in the +X direction relative to the base member 2.

FIG. 11B is a diagram illustrating a state (Phase 1) in which the tip portion 31a moves in the −X direction relative to the base member 2. In FIGS. 11A and 11B, for purposes of ease of drawing, some parts (Phases 1 and 2) of plural states (Phases N) of the driving member of the driving mechanism are shown. The driving members 31 of the first group out of two groups of driving members 3 are shown. In FIGS. 11A and 11B, the states are shown using an orthogonal coordinate system in which the moving direction of the driving members 31 in the rotation direction R of the rotor 4 is defined as an X direction (the second direction) and the moving direction of the driving members 31 along the support shaft 5 is defined as a Y direction (the first direction).

### Phase 1

For example, in a state where the tip portion 31a of the driving member 31 comes in contact with the rotor 4, a voltage of −1.0 V is generated at the first terminal T1 and the voltage is supplied to each first piezoelectric element 61 via the first wiring 11. A voltage of +3.0 V is generated at the third terminal T3 and the voltage is supplied to each second piezoelectric element 71 via the third wiring 13. Then, the first piezoelectric elements 61 driving the driving member 31 is deformed in the thickness-shear vibration mode and the base portion 31b of the driving member 31 moves toward the base member 2 (in the −Y direction). At the same time, the second piezoelectric elements 71 are deformed in the thickness-shear vibration mode and the tip portion 31a moves in the +X direction relative to the base portion 31b and the base member 2. The moving distance of the tip portion 31a is proportional to the absolute value of the voltage supplied to the second piezoelectric elements 71.

At this time, both the internal stress in the lifting direction due to the movement of the first piezoelectric elements 61 in the first direction (in the −Y direction) and the internal stress in the counter-feed direction due to the movement of the second piezoelectric elements 71 in the second direction (in the +X direction) act on the base portion 31b (particularly, the corner in the −X direction and the +Y direction interposed between the first piezoelectric elements 6 and the second piezoelectric elements 7 of the driving member 31. That is, both the internal stress in the +Y direction due to the deformation of the first piezoelectric elements 61 and the internal stress in the −X direction due to the deformation of the second piezoelectric elements 71 act on the upper-left corner of the base portion 31b and the compressing stress is concentrated thereon.

However, in this embodiment, the first piezoelectric elements 61 disposed on the first face 3f1 are formed to be separated from the first boundary 3g1 between the first face 3f1 and the second face 3f2. Accordingly, compared with the configuration in which the first piezoelectric elements and the second piezoelectric elements are formed in contact with each other at the first boundary (for example, the configuration in which the lower electrodes as a common electrode are formed in contact with each other when each piezoelectric element is of a stacked type), it is difficult for the internal stress in the lifting direction and the internal stress in the counter-feed direction to remain on the base portion. Accordingly, it is possible to suppress the compressing stress from being concentrated on the upper-left corner of the base portion 31b.

### Phase 2

Following Phase 1, a voltage of −1.0 V is generated at the first terminal T1 and the voltage is supplied to each first piezoelectric element 61 via the first wiring 11. The voltage of the third terminal T3 is maintained, for example, at 0 V and a voltage of 0 V is supplied to each second piezoelectric element 71 via the third wiring 13. Then, the first piezoelectric elements 61 driving the driving member 31 are deformed in the thickness-shear vibration mode and the base portion 31b of the driving member 31 moves toward the base member 2 (in the −Y direction). Further, the second piezoelectric elements 71 are deformed in the thickness-shear vibration mode and the tip portion 31a moves in the −X direction relative to the base portion 31b and the base member 2, for example, the positional relationship between the tip portion 31a and the base portion 31b becomes as FIG. 10.

Then, the voltage of the first terminal T1 is maintained at −1.0 V and the voltage supplied to each first piezoelectric element 61 via the first wiring 11 is maintained. A voltage of −3.0 V is generated at the third terminal T3 and the voltage is supplied to each second piezoelectric element 71 via the third wiring 13. Then, as shown in FIG. 11B, the deformation of the first piezoelectric elements 61 driving the driving member 31 in the Y direction is maintained and the state where the tip portion 31a is separated from the rotor 4 is maintained. In this state, the second piezoelectric elements 71 are deformed in the thickness-shear vibration mode and the tip portion 31a further moves in the −X direction relative to the base portion 31b and the base member 2. The moving distance of the tip portion 31a is proportional to the absolute value of the voltage supplied to the second piezoelectric elements 71.

At this time, both the internal stress in the lifting direction due to the movement of the first piezoelectric elements 61 in the first direction (in the −Y direction) and the internal stress in the counter-feed direction due to the movement of the second piezoelectric elements 71 in the second direction (in the −X direction) act on the base portion 31b (particularly, the corner in the +X direction and the +Y direction interposed between the first piezoelectric elements 6 and the second piezoelectric elements 7 of the driving member 31. That is, both the internal stress in the +Y direction due to the deformation of the first piezoelectric elements 61 and the internal stress in the +X direction due to the deformation of the second piezoelectric elements 71 act on the upper-right corner of the base portion 31b and the compressing stress is concentrated thereon.

However, in this embodiment, the first piezoelectric elements 61 disposed on the third face 3f3 are formed to be separated from the second boundary 3g2 between the third face 3f3 and the second face 3f2. Accordingly, compared with the configuration in which the first piezoelectric elements and the second piezoelectric elements are formed in contact with each other at the second boundary, it is difficult for the internal stress in the lifting direction and the internal stress in the counter-feed direction to remain on the base portion.

Accordingly, it is possible to suppress the compressing stress from being concentrated on the upper-right corner of the base portion 31b.

In the driving mechanism 1D according to this embodiment, since the first piezoelectric elements 6 are separated from the second piezoelectric elements 7, it is possible to suppress the residual stress due to the deformation of the first piezoelectric elements and the second piezoelectric elements from being generated in the base portion, compared with the configuration in which the first piezoelectric elements and the second piezoelectric elements are in contact with each other. Specifically, in the configuration in which the first piezoelectric elements and the second piezoelectric elements are in contact with each other, both the internal stress in the lifting direction due to the movement of the first piezoelectric elements in the first direction and the internal stress in the counter-feed direction due to the movement of the second piezoelectric elements in the second direction act on the base portion (particularly, the corner interposed between the first piezoelectric elements and the second piezoelectric elements). That is, both the internal stress due to the deformation of the first piezoelectric elements and the internal stress due to the deformation of the second piezoelectric elements act on the corners of the base portion, whereby the compressing stress is concentrated thereon. However, in this embodiment, since the first piezoelectric elements 6 and the second piezoelectric elements 7 are separated from each other, an escape (dissipation path) of the compressing stress concentrated on the corners of the base portion 3b is formed. Accordingly, it is possible to suppress the internal stress in the lifting direction and the internal stress in the counter-feed direction from remaining at the corners of the base portion 3b. Therefore, it is possible to provide the driving mechanism 1D which can independently control the vibrations of the members, which are driven by the piezoelectric elements 6 and 7, in two different directions and suppress the fatigue failure of the driving mechanism 1D.

According to this configuration, since the first face 3f1 and the second face 3f2 intersect each other at an acute angle, the compressing stress can be easily concentrated on the corners of the base portion 3b, compared with the configuration in which the first face 3f1 and the second face 3f2 intersect each other at an obtuse angle. Therefore, by constructing the first piezoelectric elements 6 and the second piezoelectric elements 7 to be separated from each other, it is possible to efficiently dissipate the compressing stress generated in the base portion 3b via the corners of the base portion 3b and to suppress the compressing stress from being concentrated on the corners of the base portion 3b.

According to this configuration, the base portion 3b supports the first piezoelectric elements 6 on the third face 3f3 opposed to the first face 3f1. Accordingly, compared with the configuration in which the first piezoelectric elements are disposed only on the first face 3f1, the number of positions of the base portion 3b on which the compressing stress is concentrated increases (from one corner of the base portion 3b to two corners of the base portion 3b). Therefore, the compressing stress to be dissipated is dispersed due to the configuration where the first piezoelectric elements 6 and the second piezoelectric elements 7 are separated from each other, it is possible to suppress the compressing stress from being concentrated on the corners of the base portion 3b.

According to this configuration, the first piezoelectric elements 6 disposed on the first face 3f1 are separated from the first boundary 3g1, the first piezoelectric elements 6 disposed on the third face 3f3 are separated from the second boundary 3g2, and the second piezoelectric elements 7 are formed in contact with the first boundary 3g1 and in contact with the second boundary 3g2. Accordingly, compared with the configuration in which the second piezoelectric elements 7 are separated from the first boundary 3g1 and are separated from the second boundary 3g2, it is possible to suppress the variation of the volume V2 of the tip portion 3a to be smaller. For example, when the second piezoelectric elements 7 are separated from the first boundary 3g1 and are separated from the second boundary 3g2, or when the corners (the first boundary and the second boundary) of the base portion are chamfered, it is necessary to flesh the base portion on both sides of the first boundary and the second boundary parallel to the second face and the volume of the base portion increases, thereby not suppressing the variation of the volume of the tip portion to be smaller. However, in this embodiment, since the second piezoelectric elements 7 are formed in contact with the first boundary 3g1 and in contact with the second boundary 3g2, it is necessary to flesh the base portion on only one side of the boundary parallel to the first face. Accordingly, it is easy to adjust the volume V1 of the base portion 3b and the volume V2 of the tip portion 3a and to adjust the mass of the base portion 3b and the mass of the tip portion 3a with a good balance. Therefore, it is easy to stably drive the rotor 4.

According to this configuration, since the mass of the base portion 3b is equal to the mass of the tip portion 3a, it is possible to stably drive the rotor 4, compared with the configuration in which the mass of the base portion is different from the mass of the tip portion.

In this embodiment, the driving mechanism 1D includes two groups of which each has three driving members 3 and which are driven with a predetermined phase difference, but the invention is not limited to this configuration. For example, the driving mechanism 1D may include three or more groups of which each has two or four or more driving members. That is, the number of driving members to be disposed can be appropriately changed as needed.

In this embodiment, plural (four) first piezoelectric elements 6 are disposed in the base portion 3b, but the invention is not limited to this configuration. For example, one, two, three or five or more first piezoelectric elements may be disposed in the base portion 3b. That is, the number of first piezoelectric elements to be disposed can be appropriately changed as needed.

In this embodiment, two second piezoelectric elements 7 are disposed in the base portion 3b, but the invention is not limited to this configuration. For example, one or three or more second piezoelectric elements may be disposed in the base portion 3b. That is, the number of second piezoelectric elements to be disposed can be appropriately changed as needed.

An example of a lens barrel (an interchangeable lens) and a camera including the driving mechanism according to the above-mentioned embodiments will be described below. The interchangeable lens according to this example forms a camera system along with a camera body. The interchangeable lens can be switched between an AF (Auto Focus) mode in which a focusing operation is performed under a known AF control and an MF (Manual Focus) mode in which a focusing operation is performed in response to a manual input from a photographer.

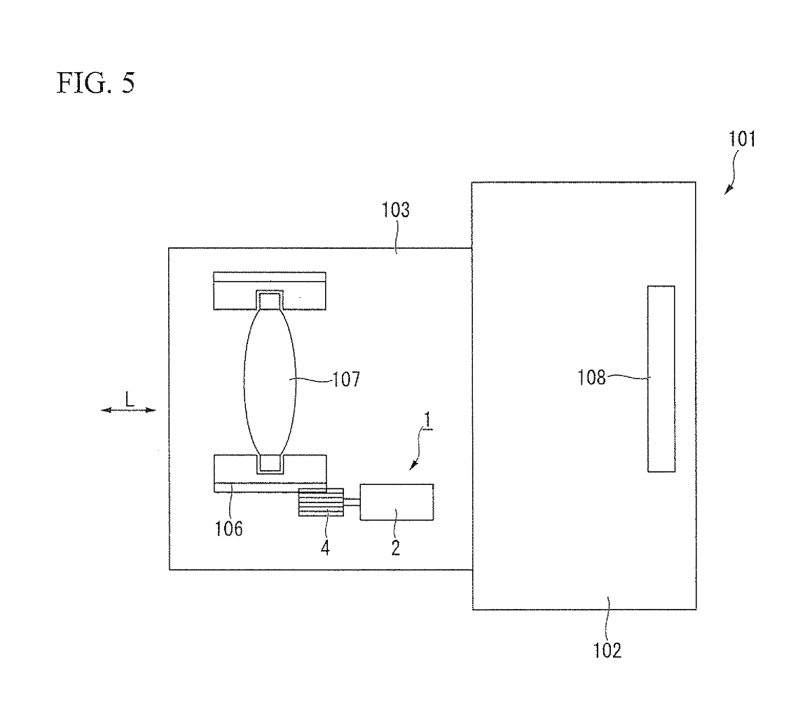

FIG. 5 is a diagram schematically illustrating the configurations of a lens barrel and a camera having the driving mechanism according to the above-mentioned embodiments. As shown in FIG. 5, a camera 101 includes a camera body 102 having an imaging device 108 built therein and a lens barrel 103 having a lens 107.

The lens barrel 103 is an interchangeable lens that can be attached to and detached from the camera body 102. The lens barrel 103 includes the lens 107, a cam box 106, and the driving mechanism 1 (or the driving mechanism 1C, the driving mechanism 1D). The driving mechanism 1 is used as a drive source driving the lens 107 in the focusing operation of the camera 101.

The driving force acquired from the rotor 4 of the driving mechanism 1 is transmitted directly to the cam box 106. The lens 107 is supported by the cam box 106 and is a focusing lens that moves substantially in parallel to the optical axis direction L to adjust the focus through the use of the driving force of the driving mechanism 1.

At the time of using the camera 101, a subject image is formed on the imaging plane of the imaging device 108 through the use of a lens group (including the lens 107) disposed in the lens barrel 103. The formed subject image is converted into an electrical signal by the imaging device 108 and image data is acquired by A/D converting the electric signal.

As described above, the camera 101 and the lens barrel 103 include the above-mentioned driving mechanism 1 (or the driving mechanism 1C, the driving mechanism 1D). Accordingly, it is possible to cause the rotor 4 to further efficiently rotate and to efficiently drive the lens 107. In addition, it is possible to independently control the vibrations in two different directions of a member to be driven by the piezoelectric elements. It is also possible to suppress the fatigue failure of the driving mechanism.

Although it has been stated in this embodiment that the lens barrel 103 is an interchangeable lens, the invention is not limited to this example and a lens barrel incorporated into the camera body may be used.

While preferred embodiments of the invention have been described, the invention is not limited to the above-mentioned embodiments. Additions, omissions, substitutions, and other modifications can be made without departing from the concept of the invention. Accordingly, the invention is not to be considered as being limited by the foregoing description, and is only limited by the scope of the appended claims.

1. A driving mechanism comprising:
a first piezoelectric element that vibrates in a thickness-shear vibration mode in a first direction;
a first member that is driven to vibrate in the first direction by the first piezoelectric element,
a second piezoelectric element that is supported by the first member and that vibrates in the thickness-shear vibration mode in a second direction; and
a second member that is driven to vibrate in the second direction by the second piezoelectric element.

2. The driving mechanism according to claim 1, wherein a longitudinal elastic coefficient of the first piezoelectric element is greater than a transverse elastic coefficient thereof, and
wherein a longitudinal elastic coefficient of the second piezoelectric element is greater than a transverse elastic coefficient thereof.

3. The driving mechanism according to claim 2, further comprising a base member that supports the first member to vibrate in the first direction via the first piezoelectric element,
wherein a longitudinal elastic coefficient of the base member is equal to or greater than the longitudinal elastic coefficient of the first piezoelectric element.

4. The driving mechanism according to claim 3, wherein the ratio (k1/kb) of the traverse elastic coefficient (k1) of the first piezoelectric element in the first direction and the longitudinal elastic coefficient (kb) of the base member is less than 0.2.

5. The driving mechanism according to claim 3, wherein the first piezoelectric element and the second piezoelectric element contain a piezoelectric zirconate titanate, and
wherein the base member contains a stainless steel.

6. A lens barrel comprising the driving mechanism according to claim 1.

7. A camera comprising the driving mechanism according to claim 1.

8. A driving mechanism comprising:
a first piezoelectric element that vibrates in a thickness-shear vibration mode in a first direction;
a first member that is driven to vibrate in the first direction by the first piezoelectric element,
a second piezoelectric element that is supported by the first member and that vibrates in the thickness-shear vibration mode in a second direction different from the first direction; and
a second member that is driven to vibrate in the second direction by the second piezoelectric element,
wherein the first member supports the first piezoelectric element on a first face parallel to the first direction and supports the second piezoelectric element on a second face parallel to the second direction, and
wherein a plurality of the first piezoelectric elements having a long-side in the first direction are arranged on the first face with an interval therebetween in a short-side direction of the first piezoelectric element.

9. The driving mechanism according to claim 8, wherein the plurality of first piezoelectric elements are arranged on both right and left sides of a first center line passing through the center of the first face and being parallel to the first direction.

10. The driving mechanism according to claim 9, wherein the plurality of first piezoelectric elements are arranged to be linearly symmetric about the first center line.

11. The driving mechanism according to claim 9, wherein the plurality of first piezoelectric elements are in contact with an edge of the first face in a direction perpendicular to the first direction.

12. The driving mechanism according to claim 8, wherein the length in the long-side direction of the first piezoelectric element is in the range of 3 to 100 times the length in the short-side direction of the first piezoelectric element.

13. The driving mechanism according to claim 8, wherein the thickness of the first piezoelectric element is in the range of 1/100 to ⅓ times the length in the short-side direction of the first piezoelectric element.

14. The driving mechanism according to claim 8, wherein a plurality of the second piezoelectric elements having a long-side in the second direction are arranged on the second face with an interval therebetween in a short-side direction of the second piezoelectric element.

15. The driving mechanism according to claim 14, wherein the plurality of second piezoelectric elements are arranged on both right and left sides of a second center line passing through the center of the second face and being parallel to the second direction.

16. The driving mechanism according to claim 15, wherein the plurality of second piezoelectric elements are arranged to be linearly symmetric about the second center line.

17. The driving mechanism according to claim 15, wherein the plurality of second piezoelectric elements are in contact with an edge of the second face in a direction perpendicular to the second direction.

18. The driving mechanism according to claim 14, wherein the length in the long-side direction of the second piezoelectric element is in the range of 3 to 100 times the length in the short-side direction of the second piezoelectric element.

19. The driving mechanism according to claim 14 wherein the thickness of the second piezoelectric element is in the range of 1/100 to ⅓ times the length in the short-side direction of the second piezoelectric element.

20. The driving mechanism according to claim 8, further comprising a base member that supports the first member on a support face with the plurality of first piezoelectric elements interposed therebetween,
wherein a rectangular shape circumscribing the plurality of first piezoelectric elements in contact with the support face of the base member is square.

21. A lens barrel comprising:
the driving mechanism according to claim 8;
a cam box that is driven by the driving mechanism; and
a lens that is movably supported by the cam box to adjust a focus.

22. A camera comprising:
the lens barrel according to claim 21; and
an imaging device that forms a subject image on an imaging plane through the use of the lens disposed in the lens barrel.

23. A driving mechanism comprising:
a first piezoelectric element that vibrates in a thickness-shear vibration mode in a first direction;
a first member that is driven to vibrate in the first direction by the first piezoelectric element,
a second piezoelectric element that is supported by the first member and that vibrates in the thickness-shear vibration mode in a second direction different from the first direction; and
a second member that is driven to vibrate in the second direction by the second piezoelectric element,
wherein the first member supports the first piezoelectric element on a first face parallel to the first direction and supports the second piezoelectric element on a second face parallel to the second direction, and
wherein the first piezoelectric element and the second piezoelectric element are separated from each other.

24. The driving mechanism according to claim 23, wherein the first face and the second face intersect each other at an acute angle.

25. The driving mechanism according to claim 23, wherein the first member supports the first piezoelectric element on a third face opposed to the first face.

26. The driving mechanism according to claim 25, wherein the first piezoelectric element disposed on the first face is separated from a first boundary between the first face and the second face,
wherein the first piezoelectric element disposed on the third face is separated from a second boundary between the third face and the second face, and
wherein the second piezoelectric element is formed to come in contact with the first boundary and to come in contact with the second boundary.

27. The driving mechanism according to claim 23, wherein the mass of the first member is equal to the mass of the second member.

28. A lens barrel comprising the driving mechanism according to claim 23.

29. A camera comprising the driving mechanism according to claim 23.
